(19) United States
(12) Patent Application Publication
(10) Pub. No.: US 2026/0231662 A1
(43) Pub. Date: Aug. 6, 2026

(54) Display Device

(71) Applicant: LG Display Co., Ltd., Seoul (KR)

(72) Inventor: Jong Hyun Yang, Paju-si (KR)

(21) Appl. No.: 19/442,434

(22) Filed: Jan. 7, 2026

(30) Foreign Application Priority Data
Jan. 31, 2025 (KR) 10-2025-0012282

(51) Int. Cl. H10K 59/88; H10K 59/121; H10K 59/131

(52) U.S. Cl. CPC H10K 59/88; H10K 59/1213; H10K 59/1216; H10K 59/131

(57) ABSTRACT

A display device presented herein includes a display region in which a plurality of pixels each including a light-emitting element are disposed, a non-display region outside the display region and in which a plurality of dummy pixels are disposed, and a plurality of repair lines crossing the display region and the non-display region along a first direction. At least some of the repair lines have a double line structure. At least one defective pixel among the pixels of the display region is electrically connected to the dummy pixel through the repair line. When a distance between the dummy pixel and the defective pixel connected to each other through the repair line is smaller than half the length of the display region in the first direction, lengths of the repair lines between the dummy pixels and the defective pixels in the display region are provided to be the same.

### CROSS-REFERENCE TO RELATED APPLICATION

The present application claims priority to Republic of Korea Patent Application No. 10-2025-0012282, filed on January, 31, 2025, which is incorporated herein by reference in its entirety.

### BACKGROUND

### Field

The present disclosure relates to a display device.

### Discussion of Related Art

Display devices are being applied to various electronic devices such as a television (TV), a mobile phone, a notebook, a tablet, and the like.

Display devices include an organic light-emitting display (OLED) device which emits light by itself, a liquid crystal display (LCD) device which requires a separate light source, and the like.

The display device may include a display panel including a plurality of subpixels and a plurality of signal lines. The display device may include a plurality of driving circuits which drive the plurality of subpixels and the plurality of signal lines.

When defects occur in circuit elements located in the subpixels or the signal lines which are disposed in the display panel, a repair process may be performed. The repair process may be performed, for example, by cutting using a laser or welding.

Specifically, during a repair process of pixels, a repair process in which a dummy pixel circuit disposed outside the display panel of the display device and a defective pixel circuit in a display region are connected by welding may be performed.

In the display device including the repair process, there is a problem in that a difference in luminance occurs between the repaired defective pixels and pixels connected to an actual normal pixel circuit depending on the difference in distance between dummy pixels disposed outside the display panel and defective pixels in the display region.

### SUMMARY

The problems to be solved according to one or more embodiments of the present disclosure is to provide a display device in which a length of a repair line between a dummy pixel and a defective pixel in a display region is maintained at a constant level to improve a difference in luminance between a pixel connected to an actual normal pixel circuit and the repaired defective pixel.

The problems to be solved according to one or more embodiments of the present disclosure are not limited to the above-mentioned problems, and other problems which are not mentioned will be clearly understood by those skilled in the art from the following description.

One or more embodiments of the present disclosure provide a display device including a display region in which a plurality of pixels each including a light-emitting element are disposed, a non-display region disposed outside the display region and in which a plurality of dummy pixels are disposed, and a plurality of repair lines crossing the display region and the non-display region along a first direction, at least some of which have a double line structure, wherein at least one defective pixel among the pixels of the display region is electrically connected to the dummy pixel through the repair line, and when a distance between the dummy pixel and the defective pixel connected to each other through the repair line is smaller than half the length of the display region in the first direction, since the distance between the dummy pixel and the defective pixel connected to each other through the repair line is set to be smaller than a distance from the dummy pixel to a welding position where the double lines of the repair line are connected to each other, lengths of the repair lines between the dummy pixels and the defective pixels in the display region are provided to be the same.

Specific details according to the various embodiments of the present disclosure other than solutions to the above-mentioned problems are included in the description and drawings described below.

### BRIEF DESCRIPTION OF THE DRAWINGS

The following drawings attached to this disclosure illustrate preferred embodiments of the present disclosure and, together with the detailed description of the disclosure to be described below, serve to further understand the technical idea of the present disclosure, and therefore the present disclosure should not be construed as being limited to matters described in such drawings, in which:

FIG. 1 is a block diagram showing a display device according to one or more embodiments of the present disclosure.

FIG. 2 is a view showing an example of a pixel circuit structure connected to a normal pixel of the display device according to one or more embodiments of the present disclosure.

FIG. 3A is a block diagram showing an example of a connection structure of dummy pixels and defective pixels included in the display device according to one or more embodiments of the present disclosure.

FIG. 3B is a block diagram showing an example of a connection structure of dummy pixels and defective pixels included in a display device according to one or more other embodiments of the present disclosure;

FIG. 4A is a view showing an example of a circuit structure of the display device according to one or more embodiments of the present disclosure.

FIG. 4B is a view showing a repair process of a pixel circuit of the display device according to one or more embodiments of the present disclosure.

FIG. 5 is a view showing an example of a structure in which the repair process is performed on the pixel circuit of the display device according to one or more embodiments of the present disclosure.

FIG. 6A is a block diagram showing an example of pixels on which the repair process of the display device is performed according to one or more embodiments of the present disclosure.

FIG. 6B is a block diagram showing an example of pixels on which a repair process of a display device is performed according to one or more other embodiments of the present disclosure .

FIG. 7A is a block diagram showing an example in which a repair process is performed on a defective pixel disposed in a 1-1 display region according to one or more other embodiments of the present disclosure;

FIG. 7B is a block diagram showing an example in which the repair process is performed on a defective pixel disposed in a 1-2 display region according to one or more other embodiments of the present disclosure.

FIG. 8A is a cross-sectional view of a pixel according to one or more embodiments of the present disclosure.

FIG. 8B is a cross-sectional view of a pixel according to one or more other embodiments of the present disclosure.

FIG. 8C is a cross-sectional view of a pixel according to one or more other embodiments of the present disclosure.

FIG. 9A is a cross-sectional view taken along line A-A' in FIG. 6A according to one or more embodiments of the present disclosure.

FIG. 9B is a cross-sectional view taken along line A-A' in FIG. 6A according to one or more other embodiments of the present disclosure.

FIG. 9C is a cross-sectional view taken along line B-B' in FIG. 6B according to one or more embodiments of the present disclosure.

### DETAILED DESCRIPTION

Advantages and features of the present disclosure, and methods of achieving them will become apparent with reference to the following embodiments, which are described in detail with the accompanying drawings. The present disclosure is not limited to the embodiments to be described below and may be implemented in various different forms, the embodiments are only provided to completely disclose the present disclosure and completely convey the scope of the present disclosure to those skilled in the art, and the present disclosure is defined only by the scope of the claims.

Since the shapes, sizes, proportions, angles, numbers, and the like disclosed in the drawings for describing the embodiments of the present disclosure are only exemplary, the present disclosure is not limited to the items shown in the drawings. The same reference number indicates the same components throughout the present disclosure. Further, in describing the present disclosure, when it is determined that a detailed description of related known technology may unnecessarily obscure the gist of the present disclosure, the detailed description thereof will be omitted.

When “providing,” “including,” “having,” “comprising,” and the like mentioned in the present disclosure are used, other parts may be added unless ‘only’ is used. A case in which a component is expressed in a singular form may also be interpreted as a plural form unless explicitly stated otherwise.

In interpreting a component, the component is interpreted as including the margin of error even when there is no separate explicit description.

When positional relationships and interconnection relationships between two components such as ‘on,’ ‘above,’ ‘below,’ ‘next to,’ ‘connect or couple,’ ‘crossing or intersecting,’ and the like are described, one or more other components may be interposed between the two components unless ‘immediately’ or ‘directly’ is mentioned.

When a temporal relationship is described as ‘after,’ following,’ ‘and then,’ ‘before,’ or the like, the temporal relationship may not be continuous on a time axis unless ‘immediately’ or ‘directly’ is used.

First, second, and the like may be used to distinguish components, but the functions or structures of these components are not limited by the ordinal numbers in front of the components or component names.

The following embodiments may be partially or fully combined with each other, and technically, various types of interconnection and driving are possible. The embodiments may be implemented independently of each other or may be implemented together in an associated relationship.

In a display device of the present disclosure, a pixel circuit and a gate driving circuit may include a plurality of transistors. The transistor may be an oxide thin film transistor (TFT) including an oxide semiconductor or a low temperature poly silicon thin film transistor (LTPS TFT) including low temperature poly silicon (LTPS).

The transistor is a three-electrode element including a gate, a source, and a drain. The source is an electrode which supplies carriers to the transistor. In the transistor, the carriers start to flow from the source. The drain is an electrode through which the carriers exit the transistor. In the transistor, the carriers flow from the source to the drain. In the case of an n-channel transistor, since the carriers are electrons, a source voltage is lower than a drain voltage so that the electrons may flow from the source to the drain. In the n-channel transistor, current flows in a direction from the drain to the source. In the case of a p-channel transistor, since the carriers are holes, the source voltage is higher than the drain voltage so that the holes may flow from the source to the drain. In the p-channel transistor, since holes flow from the source to the drain, current flows from the source to the drain. It should be noted that the source and drain of the transistor are not fixed. For example, the source and drain may be changed depending on the applied voltage. Accordingly, the present disclosure is not limited by the source and drain of the transistor. In the following description, the source and drain of the transistor will be referred to as first and second electrodes.

A gate signal may swing between a gate on voltage and a gate off voltage. The transistor is turned on in response to the gate on voltage, whereas it is turned off in response to the gate off voltage. In the case of the n-channel transistor, the gate on voltage may be a gate high voltage VGH, and the gate off voltage may be a gate low voltage VGL. In the case of the p-channel transistor, the gate on voltage may be the gate low voltage VGL, and the gate off voltage may be the gate high voltage VGH.

Hereinafter, various embodiments of the present disclosure will be described in detail with reference to the accompanying drawings.

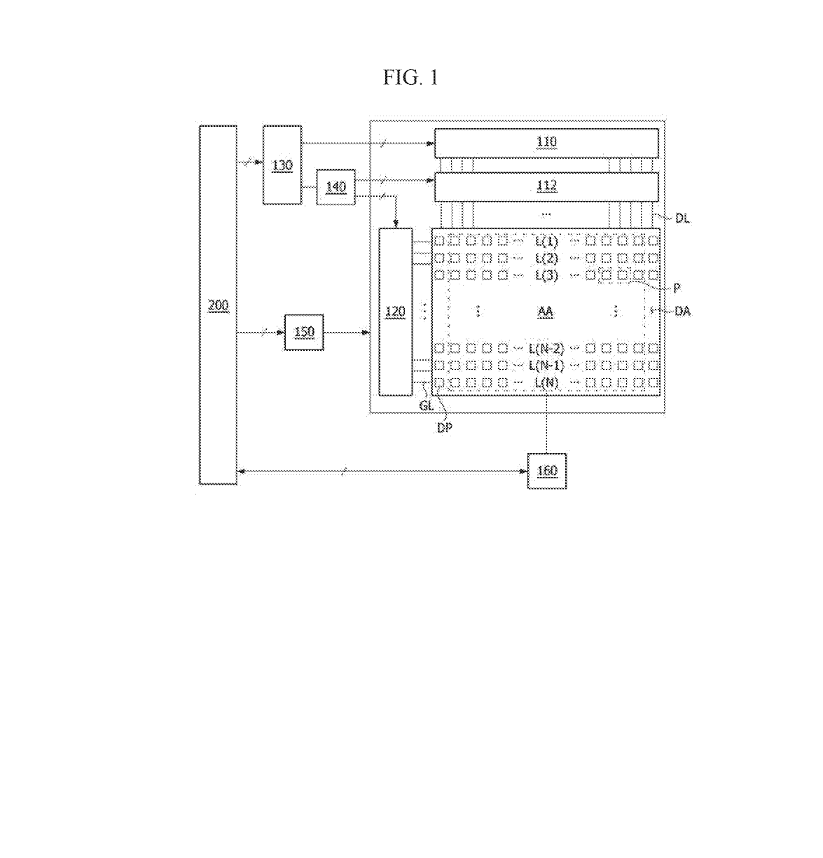

FIG. 1 is a block diagram showing a display device according to one or more embodiments of the present disclosure.

Referring to FIG. 1, the display device according to one or more embodiments of the present disclosure includes a display panel 100, a display panel driving circuit for writing pixel data to display pixels of the display panel 100, and a power supply unit 150 which generates the power required to drive the display pixels and the display panel driving circuit.

The display panel 100 may be a panel with a rectangular structure having a length in an X-axis direction, a width in a Y-axis direction, and a thickness in a Z-axis direction. The display panel 100 may be implemented as a non-transmissive display panel or transmissive display panel.

The transmissive display panel may be applied to a transparent display device in which an image is displayed on the screen and an actual background is visible. The display panel 100 may be manufactured as a flexible display panel.

A display region AA of the display panel 100 includes a pixel array which displays an input image. The pixel array includes a plurality of data lines DL, a plurality of gate lines GL intersecting the data lines DL, and display pixels disposed in a matrix form. The display panel 100 may further include power lines connected to the display pixels in common. The data lines DL may be formed long along a first direction, for example, an X-axis direction. The gate lines GL may be formed long along a second direction, for example, a Y-axis direction and may intersect the data lines DL. The power lines are connected to constant voltage nodes of the pixel circuits to supply the constant voltage required to drive display pixels P to the constant voltage nodes of the display pixels P.

Each of the display pixels P may be divided into a red subpixel, a green subpixel, and a blue subpixel to implement a color. Each of the display pixels may further include a white subpixel. Each of the subpixels includes a pixel circuit to drive a light-emitting element. Each of the pixel circuits is connected to the data lines, the gate lines, and the power lines.

The light emitting element may be implemented as an organic light-emitting diode (OLED). The light-emitting element includes an anode electrode, a cathode electrode, and an organic compound layer formed between the electrodes. The organic compound layer may include a hole injection layer (HIL), a hole transport layer (HTL), an emissive layer (EML), an electron transport layer (ETL), and an electron injection layer (EIL), but is not limited thereto. When a voltage is applied to the anode electrode and the cathode electrode of the light-emitting element, holes passing through the hole transport layer (HTL) and electrons passing through the electron transport layer (ETL) move to the emissive layer EML to form excitons. In this case, visible light is emitted from the emissive layer (EML). The light emitting element may be implemented in a tandem structure in which a plurality of emissive layers are stacked. The light emitting elements in the tandem structure may enhance the luminance and lifespan of the display pixel.

The display panel 100 may include a display region AA and a dummy region DA. The display region AA includes a plurality of pixel lines L1 to Ln. Each of the pixel lines L1 to Ln includes one line of pixels disposed along a line direction (the X-axis direction) in the display region AA of the display panel 100. The one line of pixels disposed in one pixel line share the same gate line GL. The subpixels disposed in a column direction (the Y-axis direction) along a data line direction share the same data lines DL. One horizontal period is the time acquired by dividing one frame period by the total number of pixel lines L1 to Ln. The pixel data of the input image is written to the display pixels P of the display region AA, and the input image may be displayed on the display region of the display panel 100.

The dummy region DA may be disposed to surround the outside of the display region AA. Dummy pixels DP may be disposed in the dummy region DA. The dummy pixels DP may include one line of pixels disposed along the plurality of pixel lines L1 to Ln.

The dummy pixel DP disposed in the dummy region DA may include a dummy pixel circuit. The dummy pixel circuit may be electrically connected to a pixel circuit of a defective pixel EP among the pixels disposed in the same pixel lines L1 to Ln through a repair line WDL through a repair process. A connection structure of the dummy pixel DP and the defective pixel EP will be described below in detail.

The power supply unit 150 may generate a direct current (DC) voltage (or a constant voltage) required to drive the pixel array of the display panel 100 and the display panel driving circuit using a DC-DC converter. The DC-DC converter may include a charge pump, a regulator, a buck converter, a boost converter, and the like. The power supply unit 150 may adjust a level of the DC input voltage applied from a host system 200 to output a gamma reference voltage, a constant voltage applied to the display pixels P in common, a gate on voltage, a gate off voltage, and the like. The gamma reference voltage is supplied to a data driver 110. A dynamic range of a data voltage output from the data driver 110 is determined depending on the voltage range of the gamma reference voltage. The gate-on voltage and the gate-off voltage are supplied to a level shifter 140 and a gate driver 120.

The display panel driving circuit may write the pixel data of the input image to the display pixels of the display panel 100 under the control of a timing controller 130 and senses a touch input on the display region. The display panel driving circuit includes the data driver 110, the gate driver 120, a touch sensor driver 160, and the like. The display panel driving circuit may further include a demultiplexer array 112 disposed between the data driver 110 and the data lines DL.

The data driver 110 receives the pixel data of the input image received as a digital signal from the timing controller 130 and outputs a data voltage. The data driver 110 converts the pixel data of the input image into a gamma compensation voltage using a digital to analog converter (DAC) and outputs a data voltage. The gamma reference voltage VGMA is divided into the gamma compensation voltage for each grayscale through a voltage divider circuit. The gamma compensation voltage for each grayscale is provided to the DAC of the data driver 110. The data voltage is output from each of the channels of the data driver 110 through an output buffer.

The demultiplexer array 112 sequentially supplies the data voltages output from the channels of the data driver 110 to the data lines DL using a plurality of demultiplexers (DEMUX). The demultiplexer may include a plurality of switching elements disposed on the display panel 100. When the demultiplexer is disposed between output terminals of the data driver 110 and the data lines DL, the number of channels of the data driver 110 may be reduced. The demultiplexer array 112 may be omitted.

The gate driver 120 may be formed in a circuit layer on the display panel 100 along with the TFT array and lines of the pixel array. The gate driver 120 may be disposed in a bezel area which is a non-display region of the display panel 100, or may be disposed to be distributed in the pixel array where the input image is reproduced.

The gate driver 120 may be disposed in the bezel areas (BZ) on both sides of the display panel 100 with the display region of the display panel 100 therebetween, and may supply gate pulses in a double feeding manner from both sides of the gate lines GL. In one or more other embodiments, the gate driver 120 may be disposed on one side of the left and right bezels of the display panel 100 to supply gate signals to the gate lines GL in a single feeding manner. The gate driver 120 sequentially outputs the pulses of the gate signals to the gate lines under the control of the timing controller 130. The gate driver 120 may sequentially supply the signals to the gate lines GL by shifting the pulses of the gate signals using a shift register.

The data driver 110 and the touch sensor driver 160 may be integrated into a single drive integrated circuit (IC). In a mobile terminal or wearable terminal, the timing controller 130, the power supply unit 150, the level shifter 140, the data driver 110, the touch sensor driver 160, and the like may be integrated into a single drive IC (D-IC).

A touch sensor layer includes a plurality of driving lines and a plurality of sensing lines that intersect each other. Capacitance is formed between the driving lines and sensing lines. The lines of the touch sensor layer are disposed in the display region AA.

The touch sensor driver 160 includes an analog circuit unit, a digital circuit unit, and a coordinate calculation unit. A driving signal is applied to the driving lines to charge the capacitance formed between the lines of the touch sensor layer. The analog circuit unit amplifies a voltage of the sensing lines using an amplifier and an integrator to sense a change in capacitance before and after a touch input. The digital circuit unit converts an analog touch sensing value output from the analog circuit unit into digital data using an analog to digital converter (ADC) to output touch raw data, and compares the touch raw data with a certain reference value. The touch coordinate calculation unit calculates a coordinate value of the touch raw data that is greater than the reference value and outputs touch data including the coordinate information of each touch input. The touch data output from the touch sensor driver 160 is transmitted to the host system 200. The higher the frequency at which touch data is transmitted, that is, a touch report rate, the faster the host system 200 may recognize the touch input. Accordingly, the higher the touch report rate, the better the touch input sensitivity.

The timing controller 130 receives digital video data of the input image and a timing signal synchronized with the digital video data from the host system 200. The timing signal may include a vertical synchronization signal Vsync, a horizontal synchronization signal Hsync, a clock CLK, and a data enable signal DE. Since a vertical period (or a frame period) and a horizontal period may be known by counting the data enable signal DE, the vertical synchronization signal Vsync and the horizontal synchronization signal Hsync may be omitted. The data enable signal DE has a cycle of one horizontal period 1H.

Based on the timing signal received from the host system 200, the timing controller 130 generates a data timing control signal for controlling the operation timing of the data driver 110, a MUX control signal for controlling the operation timing of the demultiplexer array 112, and a gate timing control signal for controlling the operation timing of the gate driver 120. The timing controller 130 controls the operation timing of the display panel driving circuit to synchronize the data driver 110, the demultiplexer array 112, and the gate driver 120

The gate timing control signal generated from the timing controller 130 may be input to the shift register of the gate driver 120 through the level shifter 140. The level shifter 140 may receive the gate timing control signal, generate a start pulse and a shift clock, and provide the start pulse and the shift clock to the gate driver 120. The level shifter 140 may increase a swing width of the MUX control signal of the digital signal level input from the timing controller 130 to a voltage between the gate-on voltage and the gate-off voltage, and provide the MUX control signal to the demultiplexer array 112.

The host system 200 may include a main board of any one of a television system, a navigation system, a personal computer (PC), a vehicle system, a mobile terminal, and a wearable terminal. The host system may scale an image signal from a video source to match the resolution of the display panel 100 and transmit the image signal to the timing controller 130 along with the timing signal.

In a mobile system, the host system 200 may be implemented as an application processor (AP). The host system 200 may transmit the pixel data of the input image to a drive integrated circuit (D-IC) through a mobile industry processor interface (MIPI). The host system 200 may be connected to the D-IC through, for example, a flexible printed circuit (FPC). The D-IC may bonded to the display panel 100 in a chip on glass (COG) process.

The host system 200 may execute an application program corresponding to the coordinate value at which the touch input is detected in response to the touch data received from the touch sensor driver 160.

The host system 200 converts the data received from an optical sensor into graphic image data in a capturing mode. The host system 200 compares feature point data received from the optical sensor with the user's facial data stored in advance in a facial recognition mode to process user authentication. The host system 200 determines whether there is a touch input and its location based on the touch data received from the touch sensor driver 160 and the touch data received from an optical sensor driver in the touch recognition mode.

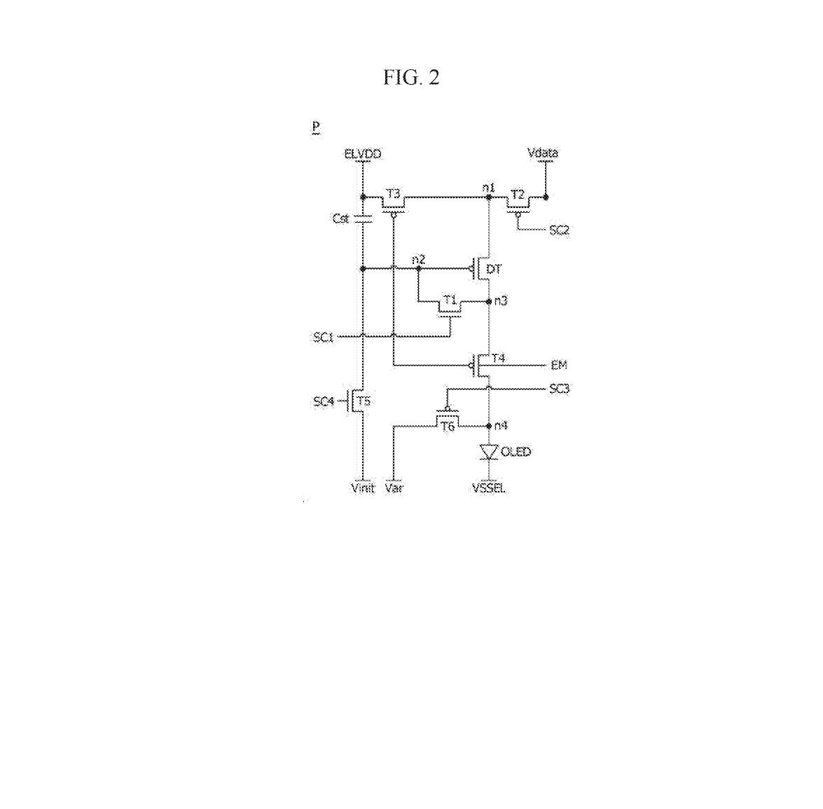

FIG. 2 is a view showing an example of a pixel circuit structure of a normal pixel according to one or more embodiments of the present disclosure.

Referring to FIG. 2, when the pixel circuit of a normal pixel P according to one or more embodiments of the present disclosure is an internal compensation circuit, a specific configuration is not specifically limited. For example, the pixel circuit of the normal pixel P may have various circuit structures such as 7T1C and 6T1C. Hereinafter, an example in which 7T1C includes an oxide transistor will be described.

The pixel circuit of the normal pixel P includes a light-emitting element OLED, a driving element DT which supplies current to the light-emitting element OLED, and an internal compensation circuit which samples a threshold voltage Vth of the driving element DT using a plurality of switching elements T1 to T6 and compensates for a gate voltage of the driving element DT by the threshold voltage Vth of the driving element DT. Here, each of the switching elements T1 and T5 may be implemented as an n-channel TFT, and each of the driving element DT and the remaining switching elements T2 to T4 and T6 may be implemented as a p-channel TFT.

The light-emitting element OLED may be implemented as an organic light-emitting diode or an inorganic light-emitting diode. Hereinafter, an example in which the light-emitting element OLED is implemented as the organic light-emitting diode will be described.

An anode electrode of the light-emitting element OLED is connected to a fourth node n4 between the fourth and sixth switching elements T4 and T6. The fourth node n4 is connected to the anode electrode of the light-emitting element OLED, a second electrode of the fourth switching element T4, and a second electrode of the sixth switching element T6. A cathode electrode of the light-emitting element OLED is connected to a VSS line VSSEL to which a low potential power voltage VSS is applied. The light-emitting element OLED emits light with a current Ids flowing according to a gate-source voltage Vgs of the driving element DT. A current path of the light-emitting element OLED is switched by the third and fourth switching elements T3 and T4.

The driving element DT controls the current Ids flowing through the light-emitting element OLED according to the gate-source voltage Vgs to drive the light-emitting element OLED. The driving element DT includes a gate connected to a second node n2, a first electrode connected to a first node n1, and a second electrode connected to a third node n3.

A storage capacitor Cst is connected between a VDD line ELVDD and the second node n2. A data voltage Vdata compensated by the threshold voltage Vth of the driving element DT is charged in the storage capacitor Cst. Since the data voltage Vdata is compensated by the threshold voltage Vth of the driving element DT in each of the pixels, a characteristic deviation of the driving element DT in the pixels is compensated.

A first switching element T1 is turned on in response to a gate-on voltage VGH of a first scan pulse SC1 to connect the second node n2 and the third node n3. The second node n2 is connected to the gate electrode of the driving element DT, a first electrode of the storage capacitor Cst, and a first electrode of the first switching element T1. The third node n3 is connected to the second electrode of the driving element DT, a second electrode of the first switching element T1, and a first electrode of a fourth switching element T4. A gate electrode of the first switching element T1 is connected to a first gate line GL1 and receives the first scan pulse SC1. A first electrode of the first switching element T1 is connected to the second node n2, and the second electrode of the first switching element T1 is connected to the third node n3.

A second switching element T2 is turned on in response to a gate-on voltage VGL of a second scan pulse SC2 to supply the data voltage Vdata to the first node n1. A gate electrode of the second switching element T2 is connected to the first gate line GL1 and receives the second scan pulse SC2. A first electrode of the second switching element T2 is connected to the first node n1. A second electrode of the second switching element T2 is connected to one of the plurality of data lines DL to which the data voltage Vdata is applied. The first node n1 is connected to the first electrode of the second switching element T2, a second electrode of a third switching element T3, and the first electrode of the driving element DT.

The third switching element T3 is turned on in response to a gate-on voltage VGL of an emission signal EM to connect the VDD line ELVDD to the first node n1. A gate electrode of the third switching element T3 is connected to a third gate line GL3 and receives the emission signal EM. A first electrode of the third switching element T3 is connected to the VDD line ELVDD. The second electrode of the third switching element T3 is connected to the first node n1.

The fourth switching element T4 is turned on in response to a gate-on voltage VGL of the emission signal EM to connect the third node n3 to the anode electrode of the light-emitting element OLED. A gate electrode of the fourth switching element T4 is connected to the third gate line GL3 and receives the emission signal EM. A first electrode of the fourth switching element T4 is connected to the third node n3, and a second electrode of the fourth switching element T4 is connected to the fourth node n4.

A fifth switching element T5 is turned on in response to a gate-on voltage VGH of a fourth scan pulse SC4 to connect the second node n2 to a Vini line PL2. A gate electrode of the fifth switching element T5 is connected to a second gate line GL2 to receive the fourth scan pulse SC4. A first electrode of the fifth switching element T5 is connected to the second node n2, and a second electrode of the fifth switching element T5 is connected to the Vini line PL2.

A sixth switching element T6 is turned on in response to a gate-on voltage VGL of a third scan pulse SC3 to connect an anode initialization voltage Var to the fourth node n4. A gate electrode of the sixth switching element T6 is connected to the first gate line GL1 to receive the third scan pulse SC3. A first electrode of the sixth switching element T6 is connected to the anode initialization voltage Var, and a second electrode of the sixth switching element T6 is connected to the fourth node n4.

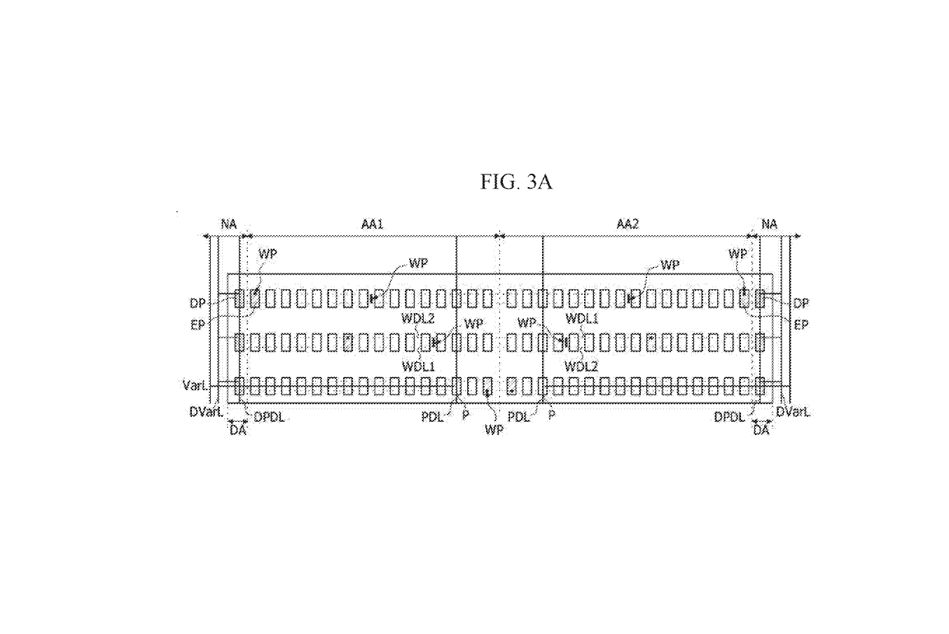

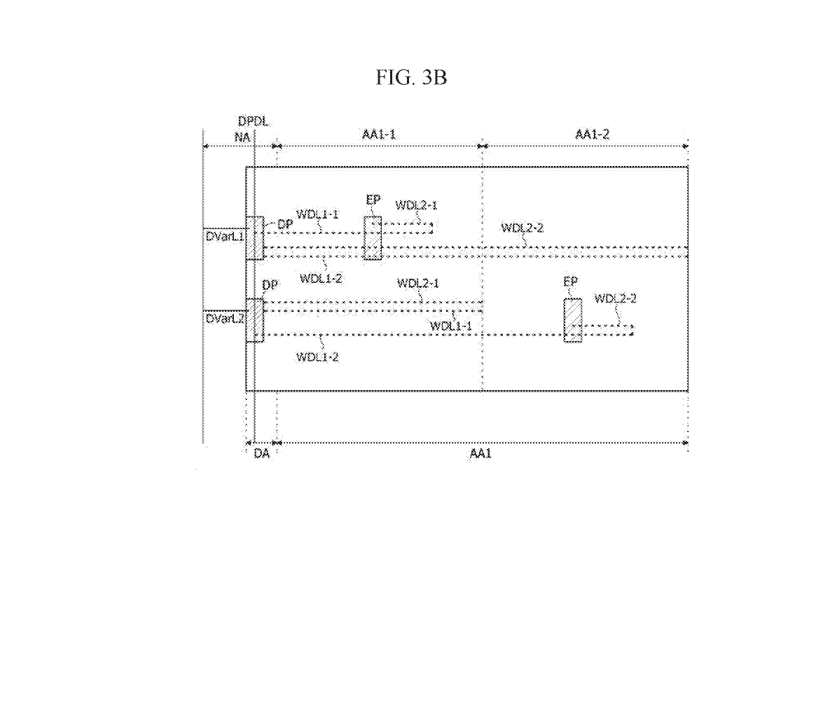

FIG. 3A is a block diagram showing an example of a connection structure of the dummy pixels and the defective pixels included in the display device according to one or more embodiments of the present disclosure.

Referring to FIG. 3A, the display region AA may include a first display region AA1 and a second display region AA2. The first display region AA1 and the second display region AA2 may be regions which divide the display region AA into half in a horizontal direction.

The display region AA may include normal pixels P and defective pixels EP in which errors occur due to defects in the signal lines, a short circuit in the pixel circuit, and the like. The dummy region DA where the dummy pixels DP are disposed may be formed in the non-display region NA disposed outside the display region AA.

The defective pixels EP disposed in the display region AA may be repaired by being connected to the dummy pixel DP disposed in the dummy region DA through repair lines WDL1 and WDL2. The dummy pixels DP disposed in the dummy region DA may be electrically connected to one of the defective pixels of the same pixel lines disposed along a line direction X of each display region AA through the repair lines WDL1 and WDL2.

The dummy pixel DP of the dummy region DA located outside the first display region AA1 is connected to the defective pixel EP of the first display region AA1, and the dummy pixel DP of the dummy region DA located outside the second display region AA2 and the defective pixel EP of the second display region AA2 may be electrically connected to each other through the repair lines WDL1 and WDL2.

The repair lines WDL1 and WDL2 may be disposed as double lines of a first repair line WDL1 and a second repair line WDL2. The first repair line WDL1 and the second repair line WDLb may be disposed in parallel along a line direction per one pixel line.

The first repair line WDL1 and the second repair line WDL2 may be connected through a process such as welding at a welding point WP disposed in the display region AA to electrically connect the dummy pixel DP and the defective pixel EP as shown in FIG. 3A.

The welding point WP of the first repair line WDL1 and the second repair line WDL2 may be located at a distance farther than a distance between the dummy pixel DP and the defective pixel EP connected through the repair lines WDLb and WDL2. That is, a cutting point of the first repair line WDL1 and the second repair line WDL2 may be disposed closer to a center of the line direction of the display region AA than the defective pixel EP.

The welding point WP between the first repair line WDL1 and the second repair line WDL2 may be disposed in the display region AA so that the sum of line lengths of the first repair line WDL1 and the second repair line WDL2 is half of a horizontal length of the display region AA.

That is, regardless of where the defective pixel EP occurs in one pixel line, the sum of the line lengths of the first repair line WDL1 and the second repair line WDL2 may be maintained as half the horizontal length of the display region AA.

As the sum of the lengths of the repair lines WDL1 and WDL2 which are the same in all regions is maintained, a difference in luminance between the defective pixel EP and the normal pixel P which may occur due to a difference in lengths of the repair lines WDL1 and WDL2 depending on the repair position may be improved.

In order to improve the difference in luminance between the defective pixel EP and the normal pixel P, since a dummy anode initialization voltage DVar different from the anode initialization voltage Var applied to the normal pixel P is applied through a dummy anode initialization voltage line DVarL, an anode initialization voltage applied to the dummy pixel DP of the dummy region DA may be applied to the defective pixel EP through the repair lines WDL1 and WDL2.

When the distance between the dummy pixel DP and the defective pixel EP connected to each other through the repair line WDL coincides with half the distance of the display region AA in the horizontal direction, the repair lines WDL1 and WDL2 may connect the dummy pixel DP and the defective pixel EP using only one of the first repair line WDL1 and the second repair line WDL2.

The non-display region NA may include the dummy region DA where the dummy pixels are disposed and a line region in which the pixel lines required to drive the pixels are disposed. The line region may include an anode initialization voltage line VarL which applies the anode initialization voltage Var to the normal pixel and the dummy anode initialization voltage line DVarL which applies the dummy anode initialization voltage DVar to the dummy pixel.

The data voltage Vdata may be applied to the normal pixel P in the display region AA through a data line PDL, and a dummy data voltage DVdata may be applied to the dummy pixel DP disposed in the dummy region DA of the non-display region NA through a dummy data line DPDL to be applied to the light-emitting element of the defective pixel EP through the repair line WDL.

When the pixel circuit of the defective pixel EP and the pixel circuit of the dummy pixel DP are connected through the repair lines WDL1 and WDL2, and VDD, the data voltage Vdata, the dummy anode initialization voltage DVar, and the like are applied to the light-emitting element OLED of the defective pixel EP using the pixel circuit of the dummy pixel DP, a difference in luminance between the normal pixel P and the repaired defective pixel EP may occur due to factors such as resistance and parasitic capacitance of the extended repair line or the like. Among the above, when the same anode initialization voltage Var as that of the normal pixel P is applied due to the difference in lengths of the repair lines WDL1 and WDL2, a difference in luminance may occur due to the difference in lengths of the repair lines WDL1 and WDL2 between the normal pixel P and the repaired defective pixel EP specifically in a low-grayscale range.

Accordingly, the dummy anode initialization voltage DVar which is different from the anode initialization voltage Var applied to the normal pixel P may be applied to the repaired defective pixel EP to similarly match the low-grayscale characteristics of the repaired defective pixel EP to the normal pixel P. For example, the dummy anode initialization voltage DVar which is -0.5 to -1 V lower than the anode initialization voltage Var of the normal pixel P may be separately applied to the repaired defective pixel EP.

Since the same dummy anode initialization voltage DVar is applied to all the repaired defective pixels EP, the sum of the lengths of all the repair lines WDL1 and WDL2 may be set to be the same as half the horizontal length of the display region AA to prevent a difference in luminance due to a difference in lengths of the repair lines WDL1 and WDL2. In order to set the sum of the lengths of all the repair lines WDL1 and WDL2 to be the same as half the horizontal length of the display region AA, the welding point WP where the first repair line WDL1 and the second repair line WDL2 are connected may be disposed closer to the center of the line direction of the display region AA than the defective pixel EP.

FIG. 3B is a block diagram showing an example of a connection structure of dummy pixels and defective pixels included in a display device according to one or more other embodiments of the present disclosure.

Referring to FIG. 3B, a first display region AA1 of the display device according to one or more other embodiments of the present disclosure may further include a 1-1 display region AA1-1 and a 1-2 display region AA1-2. The 1-1 display region AA1-1 and the 1-2 display region AA1-2 may be regions which divide the first display region AA1 into half in a horizontal direction, that is, each divided display region AA1-1 or AA1-2 may be a region which uniformly divides the display region AA into four, but is not limited thereto, and may be freely divided so that the sum of the regions of the 1-1 display region AA1-1 and the 1-2 display region AA1-2 becomes the first display region AA1.

In the present disclosure, a case in which the 1-1 display region AA1-1 and the 1-2 display region AA1-2 divide the first display region AA1 into half in the horizontal direction is shown and described.

When a defective pixel EP occurs among the pixels disposed in the 1-1 display region AA1-1, a pixel circuit of a dummy pixel DP and a pixel circuit of the defective pixel EP may be electrically connected using a 1-1 repair line WDL1-1 and a 2-1 repair line WDL2-1.

The sum of the lengths of the 1-1 repair line WDL1-1 and the 2-1 repair line WDL2-1 when the defective pixel EP occurs in the 1-1 display region AA1-1 may be the same as a horizontal length of the 1-1 display region AA1-1.

As a dummy anode initialization voltage DVar1 applied to a pixel circuit of the dummy pixel DP of a dummy region DA connected to the pixel circuit of the defective pixel EP of the 1-1 display region AA1-1 , a 1-1 dummy anode initialization voltage DVar1-1 may be applied to the pixel circuit of the dummy pixel DP through a 1-1 dummy anode initialization voltage line DVar1-1. That is, when the display region is divided as shown in FIG. 3B and the sum of the lengths of the double repair lines of each display region AA1-1 and AA1-2 is constant, a dummy anode initialization voltage DVar may be applied differently depending on the sum of the lengths of the double repair lines per one region AA1-1 or AA1-2.

In the case of a display device in which a small display panel such as a mobile and wearable display device is disposed, since a difference in luminance between the normal pixel P and the repaired defective pixel EP due to the resistance and parasitic capacitance of the repair line disposed in the 1-1 display region AA1-1 is not large, the dummy anode initialization voltage DVar1 and the dummy data voltage applied to the dummy pixel DP connected to the defective pixel EP of the 1-1 display region AA1-1 may be the same as the anode initialization voltage Var and the data voltage applied to the normal pixel P.

Without being limited thereto, even in a medium or large display panel, the range of the 1-1 display region may be limited and arranged so that the dummy anode initialization voltage DVar1 and the dummy data voltage applied to the 1-1 display region AA1-1 are the same as the anode initialization voltage Var and the data voltage applied to the normal pixel P.

When a defective pixel EP occurs among the pixels disposed in the 1-2 display region AA1-2, the sum of the lengths of a 1-2 repair line WDL1-2 and a 2-2 repair line WDL2-2 may be the same as the horizontal length of the first display region AA1 as in the first embodiment in FIG. 3A. Naturally, a dummy anode initialization voltage DVar2 applied to the pixel circuit of the dummy pixel DP of the dummy region DA connected to the pixel circuit of the defective pixel EP of the 1-2 display region AA1-2 is the same as the dummy anode initialization voltage DVar applied to the pixel circuit of the dummy pixel DP in FIG. 3A.

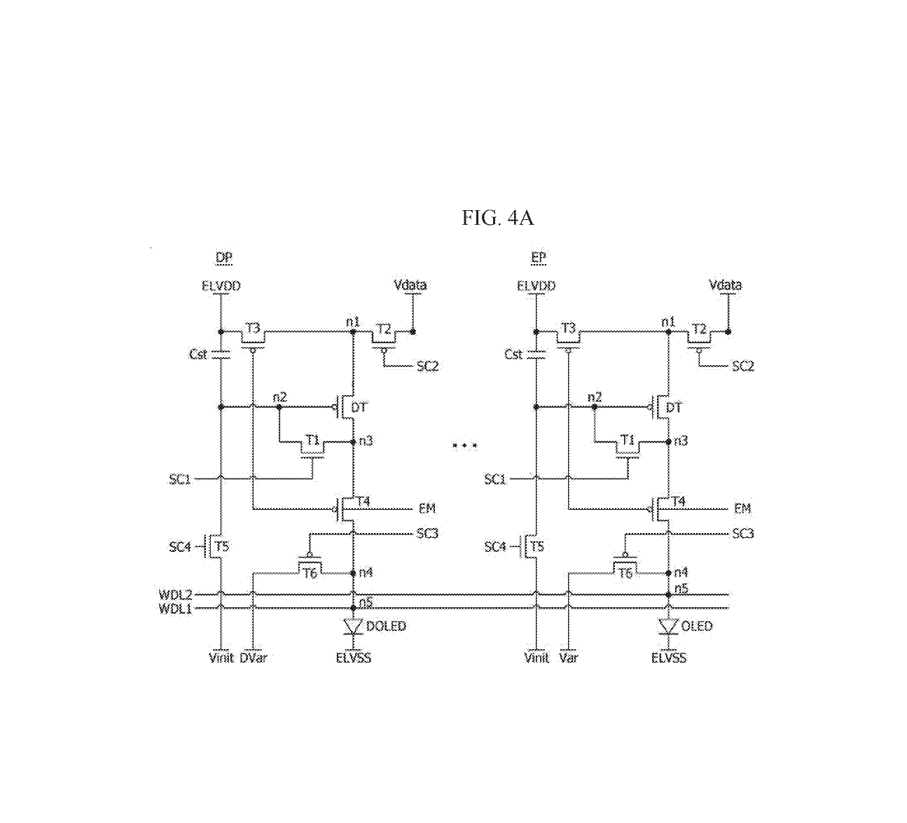

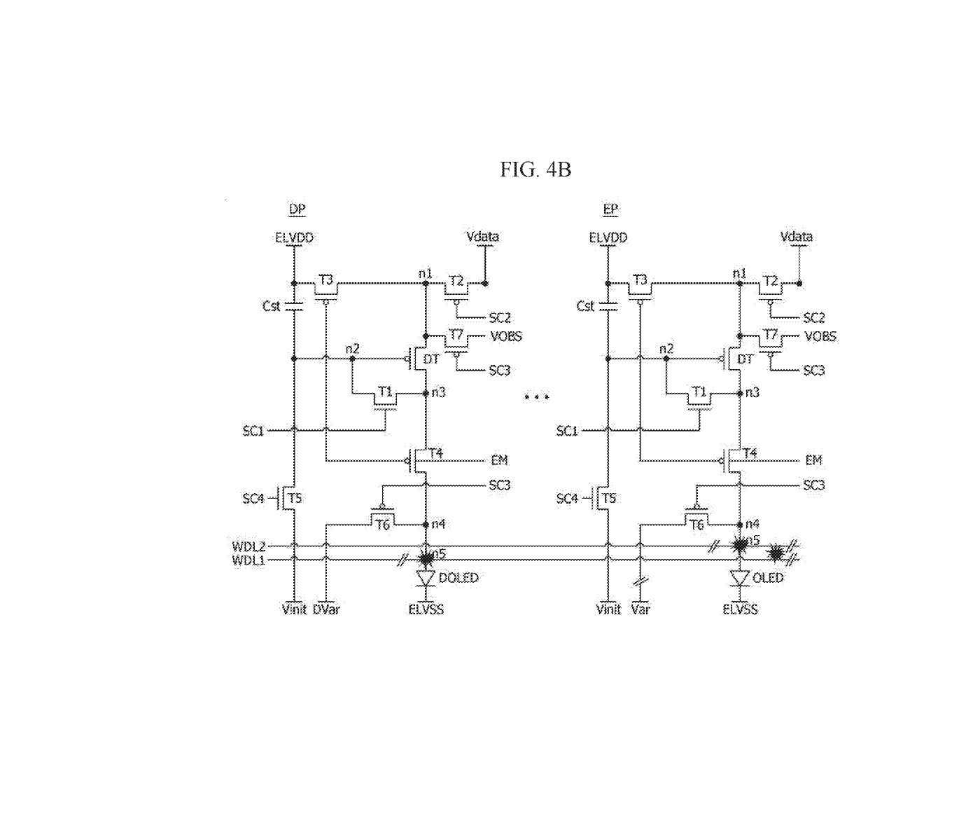

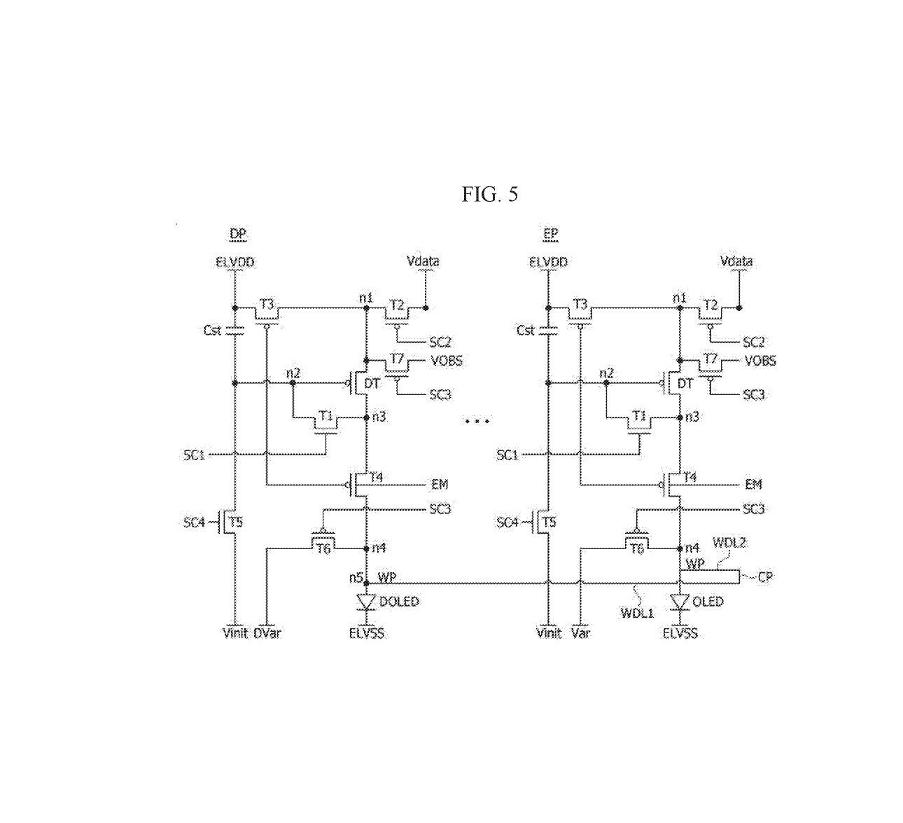

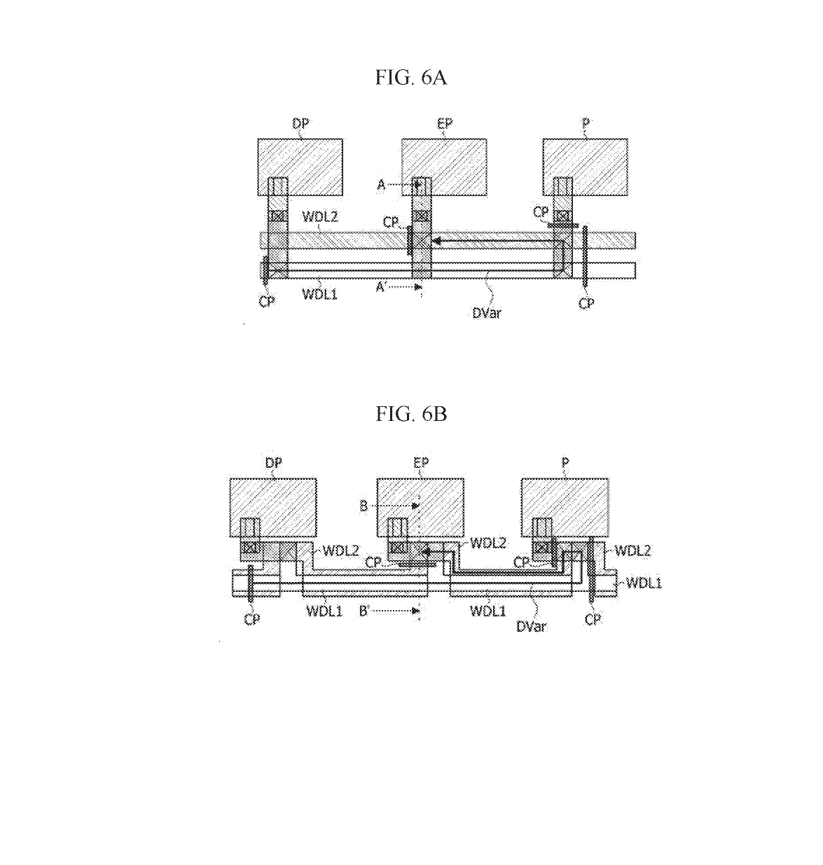

FIG. 4A is a view showing an example of a circuit structure of the display device according to one or more embodiments of the present disclosure. FIG. 4B is a view showing a repair process of the pixel circuit of the display device according to one or more embodiments of the present disclosure. FIG. 5 is a view showing an example of a structure in which the repair process is performed on the pixel circuit of the display device according to one or more embodiments of the present disclosure. FIG. 6A is a block diagram showing an example of the pixels on which the repair process of the display device is performed according to one or more embodiments of the present disclosure. FIG. 6B is a block diagram showing an example of pixels on which a repair process of a display device is performed according to one or more other embodiments of the present disclosure.

Referring to FIGS. 4A to 6B, the first repair line WDL1 and the second repair line WDL2 may be disposed in parallel between the light-emitting element OLED and the fourth node n4 of each pixel circuit. The first repair line WDL1 and the second repair line WDL2 are shown as being disposed in parallel in FIGS. 4A to 5, but are not limited thereto, a structure in which, the sum of the lengths of the first repair line WDL1 and the second repair line WDL2 may be maintained at a constant level after repair such as when the first repair line WDL1 and the second repair line WDL2 overlap in a height direction and are disposed at different positions in an overlapping manner as shown in FIG. 6B, may be used.

The first repair line WDL1 and the second repair line WDL2 may be cut and welded as shown in FIGS. 4B and 5 to electrically connect the pixel circuit of the dummy pixel DP and the pixel circuit of the defective pixel EP.

Referring to FIG. 4B, the first repair line WDL1 may be cut and welded between the fourth node n4 of the pixel circuit of the dummy pixel DP and a dummy light-emitting element DOLED to form a fifth node n5.

The welding points WP of the first repair line WDL1 and the second repair line WDL2 may be disposed and cut so that the sum of the lengths of the first repair line WDL1 and the second repair line WDL2 becomes half the horizontal length of the display region AA.

The second repair line WDL2 may be cut and welded between the fourth node n4 of the pixel circuit of the defective pixel EP and the light-emitting element OLED to form the fifth node n5.

The dummy anode initialization voltage line DVarL to which the dummy anode initialization voltage DVar different from the anode initialization voltage Var applied to the normal pixel P and the defective pixel EP of the display region as the anode initialization voltage applied to the pixel circuit of the dummy pixel DP is applied may be connected to the second electrode of the sixth switching element T6.

Finally, as shown in FIG. 5, since the pixel circuit of the dummy pixel DP and the pixel circuit of the defective pixel EP are electrically connected through the repair lines WDL1 and WDL2, and thus the device voltage VDD, the data voltage Vdata, the dummy anode initialization voltage DVar, and the like are normally applied to the light-emitting element OLED of the defective pixel EP, the defective pixel EP may be repaired.

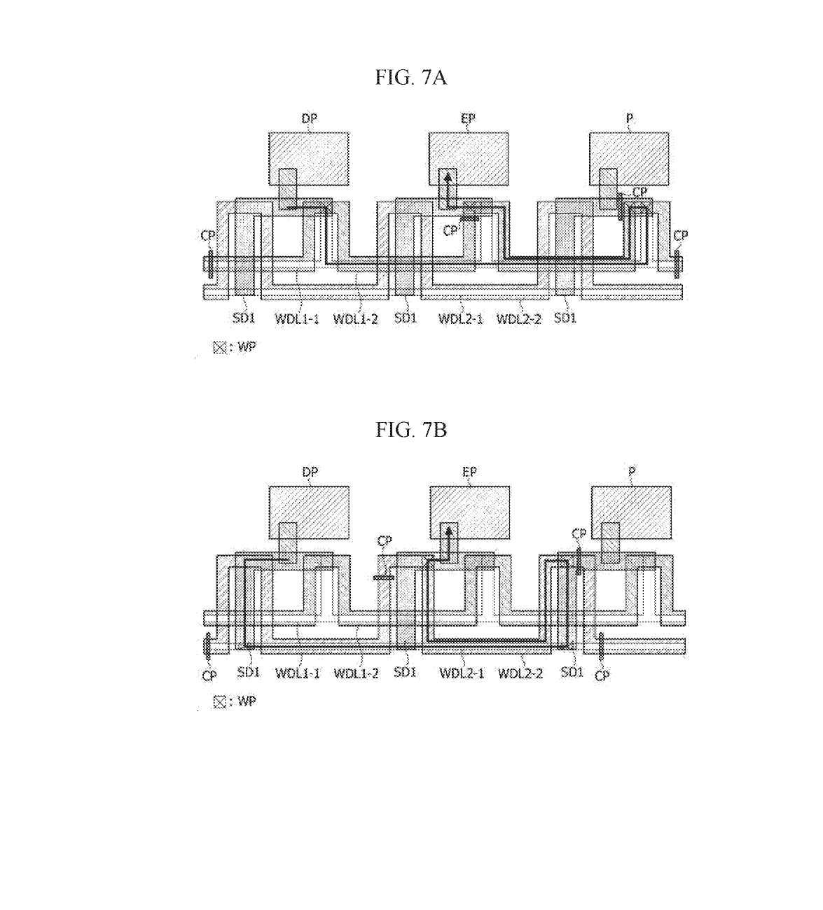

FIG. 7A is a block diagram showing an example in which a repair process is performed on a defective pixel disposed in a 1-1 display region according to one or more other embodiments of the present disclosure. FIG. 7B is a block diagram showing an example in which the repair process is performed on a defective pixel disposed in a 1-2 display region according to one or more other embodiments of the present disclosure.

Referring to FIGS. 7A and 7B, when the repair process is performed by dividing a first display region AA1 into a 1-1 display region AA1-1 and a 1-2 display region AA1-2 as in one or more other embodiments of the present disclosure, double overlapping repair lines in the height direction may be formed.

Referring to FIG. 7A, after a repair process of a defective pixel EP disposed in the 1-1 display region AA1-1 is performed, electrical signals such as a dummy anode initialization voltage DVar, a dummy data voltage DVdata, and an emission signal applied from a pixel circuit of a dummy pixel DP are applied to a 1-1 repair line WDL1-1 through a welding point WP. The 1-1 repair line WDL1-1 is connected to a 1-2 repair line WDL1-2 at the welding point WP closer to a center of the display region AA than the defective pixel EP, and the 1-2 repair line WDL1-2 may be connected to the defective pixel EP through the welding point WP. In this case, the sum of the lengths of the 1-1 repair line WDL1-1 and the 1-2 repair line WDL1-2 may be the same as the horizontal length of the 1-1 display region AA1-1.

Referring to FIG. 7B, after a repair process of a defective pixel EP disposed in the 1-2 display regions AA1-2 is performed, electrical signals such as a dummy anode initialization voltage DVar, a dummy data voltage DVdata, and an emission signal applied from the pixel circuit of the dummy pixel DP are applied to a 2-1 repair line WDL2-1 through the welding point WP. The 2-1 repair line WDL2-1 is connected to a 2-2 repair line WDL2-2 at the welding point WP closer to the center of the display region AA than the defective pixel EP, and the 2-2 repair line WDL2-2 may be connected to the defective pixel EP through the welding point WP. In this case, the sum of the lengths of the 2-1 repair line WDL2-1 and the 2-2 repair line WDL2-2 may be the same as the horizontal length of the 1-2 display region AA1-2.

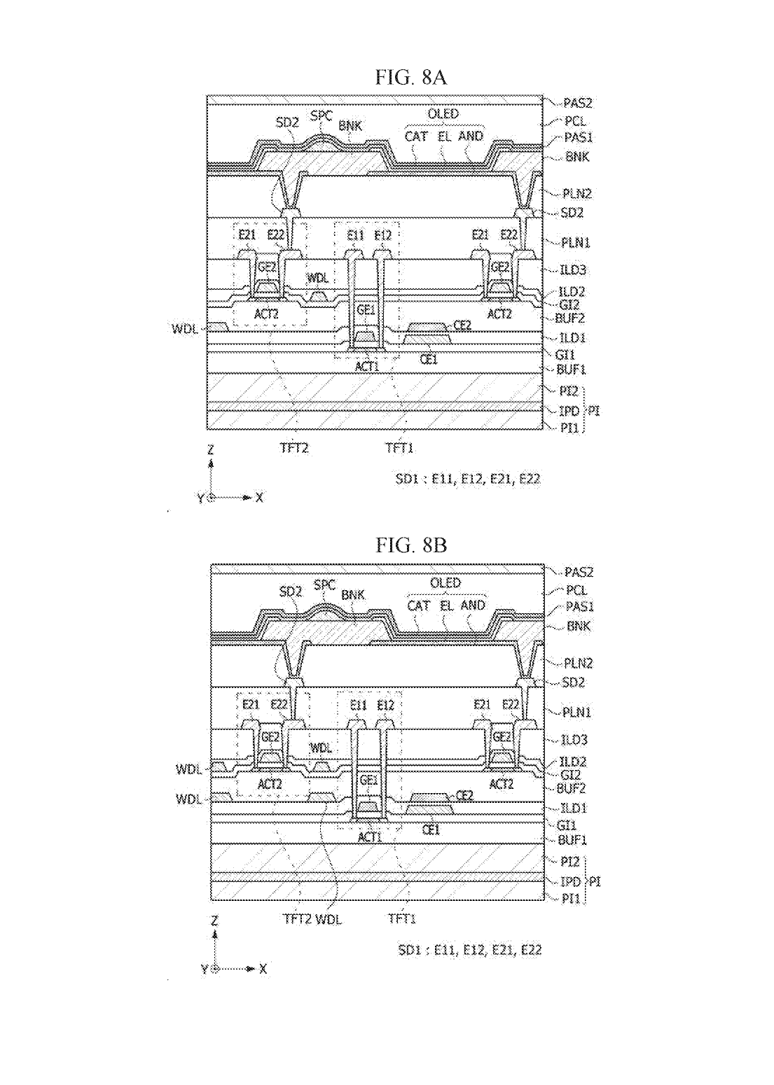

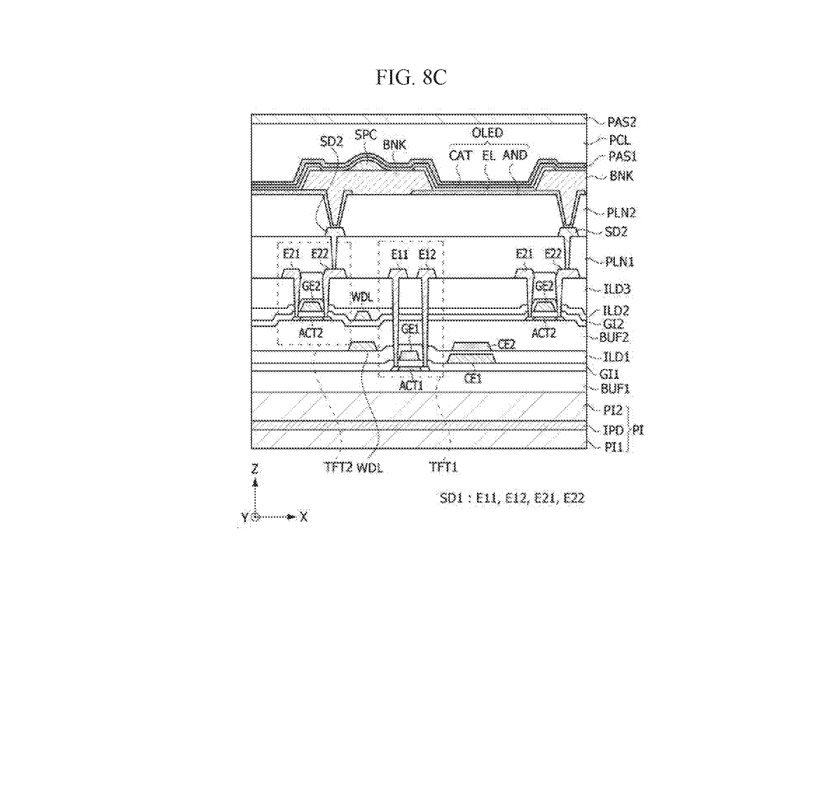

FIG. 8A is a cross-sectional view of a pixel according to one or more embodiments of the present disclosure. FIG. 8B is a cross-sectional view of a pixel according to one or more other embodiments of the present disclosure. FIG. 8C is a cross-sectional view of a pixel according to one or more other embodiments of the present disclosure.

FIG. 8A is a cross-sectional view conceptually showing a cross-sectional structure of a normal pixel among the pixel region disposed in the display region in the display panel according to one or more embodiments of the present disclosure. Here, it should be noted that the cross-sectional structure of the pixel region is not limited to FIG. 8A. In FIG. 8A, the TFT may represent a driving element of a pixel circuit. Specifically, one of the TFTs disposed in one pixel may be a first TFT which is one of the LTPS TFTs disposed in the display region, and another TFT may be a second TFT which is one of the oxide TFTs disposed in the display region.

Referring to FIGS. 8A to 8C, a plurality of pixel circuits and lines connected to the pixel circuits may be disposed in the display region AA of the display panel 100. Here, the pixel circuits of the display region may include a pixel circuit of a red subpixel which drives a red light-emitting element, a pixel circuit of a green subpixel which drives a green light-emitting element, and a pixel circuit of a blue subpixel which drives a blue light-emitting element. Further, the pixel circuits may be separated into a plurality of circuit regions along the X-axis direction of the display panel 100 in the display region AA.

A substrate PI may include a first substrate PI1 and a second substrate PI2. Further, an inorganic film IPD may be formed between the first substrate PI1 and the second substrate PI2. In this case, the inorganic film IPD may block moisture penetration. Here, the substrate PI may be formed of polyimide and thus may be referred to as a PI substrate, and the first and second substrates PI1 and PI2 may be referred to as first and second PI substrates.

A first buffer layer BUF1 may be formed on the second substrate PI2. The first buffer layer BUF1 may be formed of a multi-layer insulating film in which two or more oxide films (SiO₂) and nitride films (SINₓ) are stacked. A first semiconductor layer is formed on the first buffer layer BUF1. The first semiconductor layer may include a polysilicon semiconductor layer patterned in a photolithography process. The first semiconductor layer may include a polysilicon active pattern ACT1 forming a semiconductor channel in a first TFT TFT1.

A first gate insulating layer GI1 is deposited on the first buffer layer BUF1 to cover the active pattern ACT1 of the first semiconductor layer. The first gate insulating layer GI1 includes an inorganic insulating material layer. A first metal layer is formed on the first gate insulating layer GI1. The first metal layer is insulated from the first semiconductor layer by the first gate insulating layer GI1.

The first metal layer may include metal patterns in which a single metal layer or two or more metal layers patterned in a photolithography process are stacked. The first metal layer may include a gate electrode GE1 of the first TFT TFT1 and a lower capacitor electrode CE1.

A first interlayer insulating layer ILD1 is formed on the first gate insulating layer GI1 to cover the patterns of the first metal layer. The first interlayer insulating layer ILD1 may include an inorganic insulating material. A second buffer layer BUF2 is formed on the first interlayer insulating layer ILD1. The second buffer layer BUF2 may include a single-layer or multi-layer inorganic insulating material.

A second metal layer may be disposed on the first interlayer insulating layer ILD1. The second metal layer may include an upper capacitor electrode CE2. A capacitor Cst of the pixel circuit may be formed of the upper capacitor electrode CE2, the lower capacitor electrode CE1, and a dielectric layer between the upper capacitor electrode CE2 and the lower capacitor electrode CE1, that is, the first interlayer insulating layer ILD1.

The second semiconductor layer may include an oxide semiconductor pattern ACT2 forming a semiconductor channel in a second TFT TFT2. A second gate insulating layer GI2 may be deposited on the second buffer layer BUF2 to cover the active pattern ACT2 of the second semiconductor layer. The second gate insulating layer GI2 may include a single-layer or multi-layer inorganic insulating material. A third metal layer may be formed on the second gate insulating layer GI2. The third metal layer may be insulated from the second semiconductor layer by the second gate insulating layer GI2.

The third metal layer may include metal patterns in which a single metal layer or two or more metal layers patterned in a photolithography process are stacked. The third metal layer may include a gate electrode GE2 of the second TFT TFT2.

A second interlayer insulating layer ILD2 may be formed on the second gate insulating layer GI2 to cover the patterns of the second metal layer. The second interlayer insulating layer ILD2 may include a single-layer or multi-layer inorganic insulating material.

A third interlayer insulating layer ILD3 which covers the patterns of the third metal layer may be formed on the second interlayer insulating layer ILD2. The third interlayer insulating layer ILD3 may include a single-layer or multi-layer inorganic insulating material. A fourth metal layer may be formed on the third interlayer insulating layer ILD3. The fourth metal layer may be insulated from the second semiconductor layer by the second gate insulating layer GI2.

The fourth metal layer SD1 may include metal patterns in which a single metal layer or two or more metal layers patterned in a photolithography process are stacked. The fourth metal layer may include first and second electrodes E11 and E12 of the first TFT TFT1, and first and second electrodes E21 and E22 of the second TFT TFT2. The first and second electrodes E11 and E12 of the first TFT TFT1 may be connected to the first active pattern ACT1 through a first contact hole passing through the insulating layers GI1, ILD1, BUF2, GI2, ILD2, and ILD3. The first and second electrodes E21 and E22 of the second TFT TFT2 may be connected to the second active pattern ACT2 through a second contact hole passing through the insulating layers GI2, ILD2, and ILD3. Here, in the metal patterns of the fourth metal layer, a high-intensity electric field may be generated due to voltages swinging between the gate-on voltage and the gate-off voltage with a large voltage difference.

A first planarization layer PLN1 may cover the metal patterns of the fourth metal layer. The first planarization layer PLN1 may thickly cover the display region AA of the circuit layer with an organic insulating material. When the first planarization layer PLN is applied on the circuit layer, the organic insulating material may flow to an edge of the display panel 100 and cover a side surface of the circuit layer.

A fifth metal layer may be formed on the first planarization layer PLN1. The fifth metal layer may be insulated from the fourth metal layer by the first planarization layer PLN1. The fifth metal layer may include metal patterns in which a single metal layer or two or more metal layers patterned in a photolithography process are stacked. The fifth metal layer may include a metal pattern SD2 that connects the light emitting element to the second TFT TFT2. The metal pattern SD2 may be connected to the second electrode E22 of the second TFT TFT2 through a fourth contact hole passing through the first planarization layer PLN1.

A second planarization layer PLN2 may be formed on the first planarization layer PLN1 to cover the metal patterns of the fifth metal layer. The second planarization layer PLN2 may thickly cover the display region AA of the circuit layer with an organic insulating material. A sixth metal layer may be formed on the second planarization layer PLN2. The second planarization layer PLN2 may planarize a surface on which the sixth metal layer is formed.

The sixth metal layer may include metal patterns in which a single metal layer or two or more metal layers patterned in a photolithography process are stacked. The pattern of the sixth metal layer may include an anode electrode AND of the light-emitting element. The anode electrode AND may be in contact with the metal pattern SD2 connected to the second TFT TFT2 of the pixel circuits through a fifth contact hole passing through the second planarization layer PLN2.

In the light-emitting element layer, a bank BNK may be formed on the second planarization layer PLN2 to cover an edge of the anode electrode AND. In this case, the bank BNK may be formed as a pattern to distinguish the light-emitting regions (or opening regions) through which light is emitted from each of the pixels to the outside. Accordingly, the bank BNK may be referred to as a pixel definition film. The bank BNK may include an organic insulating material having photosensitivity and may be patterned in the photolithography process. Further, a spacer SPC having a certain height may be formed on the bank BNK. In this case, the bank BNK and the spacer SPC may be integrated with the same organic insulating material. Further, the spacer SPC may secure a gap between a fine metal mask FMM and the anode electrode AND so that the FMM does not come into contact with the anode electrode AND in a deposition process of the light-emitting element formed of an organic compound.

A seventh metal layer used as a cathode electrode CAT of the light-emitting element may be formed on the bank BNK and an organic compound layer EL. The seventh metal layer may connect between the subpixels in the display region AA. Here, the organic compound layer EL may be referred to as an emissive layer or an electroluminescent layer.

An encapsulation layer may include a multi-layer insulating layer which covers the cathode electrode CAT of the light-emitting element. The multi-layer insulating layer may include a first inorganic insulating layer PAS1 which covers the cathode electrode CAT, a thick organic insulating layer PCL which covers the first inorganic insulating layer PAS1, and a second inorganic insulating layer PAS2 which covers the organic insulating layer PCL.

The repair line WDL may be disposed on the first interlayer insulating layer IDL1 and/or the second gate insulating layer GI2. For example, as shown in FIG. 8A, one repair line WDL may be formed together when the second metal layer is formed on the first interlayer insulating layer ILD1.

Another repair line WDL may be formed together when the third metal layer is formed on the second gate insulating layer GI2 without overlapping the repair line WDL disposed on the first gate insulating layer GI1 in the height direction.

Further, the repair lines WDL may be disposed to overlap on the first interlayer insulating layer ILD1 and the second gate insulating layer GI2 in the height direction on both sides of the second TFT TFT2, as shown in FIG. 8B, or may be disposed to overlap on the first interlayer insulating layer ILD1 and the second gate insulating layer GI2 in the height direction only between the first TFT TFT1 and the second TFT TFT2 as shown in FIG. 8C. The repair lines WDL may include metal patterns in which a single metal layer or two or more metal layers patterned in a photolithography process are stacked. In other words, the second metal layer or metal pattern such as the upper capacitor electrode CE2 may be used as the repair line WDL disposed on the first interlayer insulating layer ILD1 among the repair lines WDL, and the third metal layer or metal pattern such as the gate electrode GE2 of the second TFT TFT2 may be used as the repair line WDL disposed on the second gate insulating layer GI2 among the repair lines WDL.

Without being limited thereto, the repair line WDL may be formed together when the first to third metal layers disposed under the fourth metal layer are formed.

The repair line WDL disposed on the first interlayer insulating layer ILD1 may be the first repair line WDL1 and the repair line WDL disposed on the second interlayer insulating layer ILD2 may be the second repair line WDL2, but it is not limited thereto, and the repair line WDL disposed on the first interlayer insulating layer ILD1 may be the second repair line WDL2 and the repair line WDL disposed on the second interlayer insulating layer ILD2 may be the first repair line WDL1.

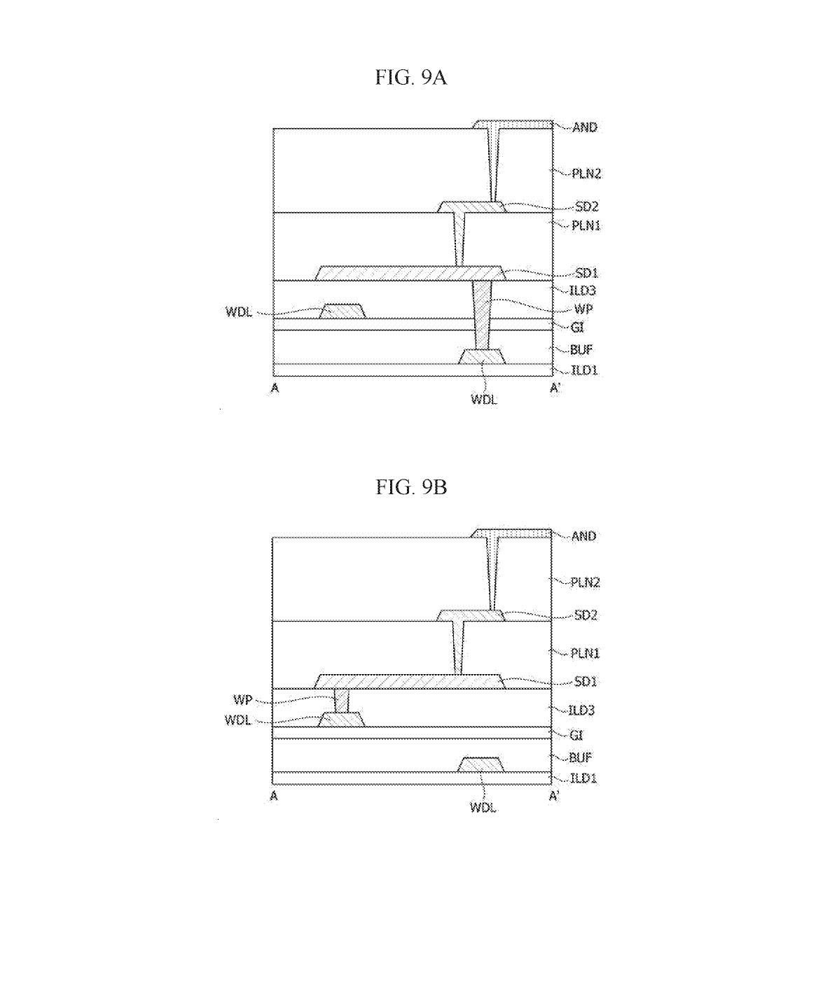

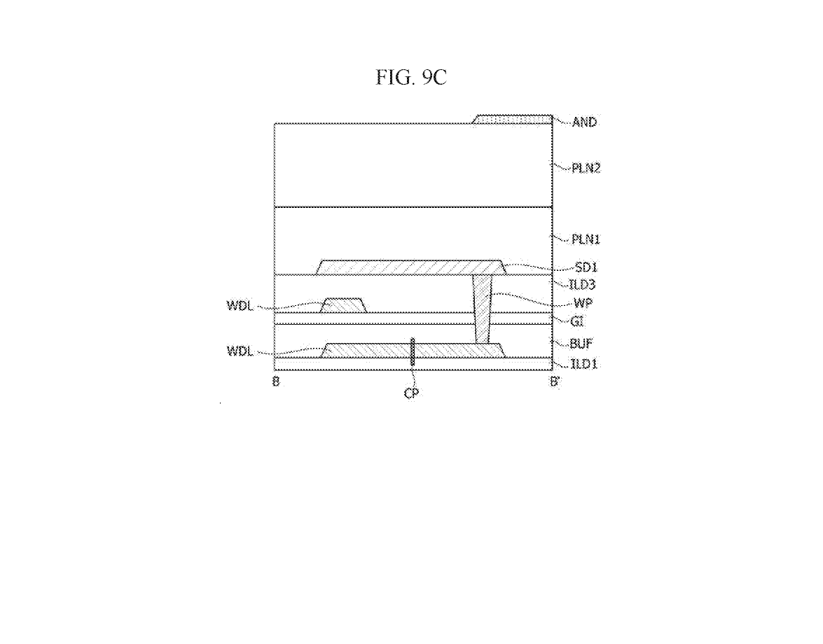

FIG. 9A is a cross-sectional view taken along line A-A' in FIG. 6A according to one or more embodiments of the present disclosure. FIG. 9B is a cross-sectional view taken along line A-A' in FIG. 6A according to one or more other embodiments of the present disclosure. FIG. 9C is a cross-sectional view taken along line B-B' in FIG. 6B according to one or more embodiments of the present disclosure.

Referring to FIGS. 9A and 9B, the fourth metal layer SD1 electrically connected to the anode electrode AND of the defective pixel EP through the electrode pattern SD2 may be connected to the repair line WDL disposed on the first interlayer insulating layer ILD1 through the welding point WP. In this case, the repair line WDL disposed on the first interlayer insulating layer ILD1 may be the second repair line WDL2, and the repair line WDL disposed on the gate insulating layer GI may be the first repair line WDL1 electrically connected to the dummy pixel DP of the dummy region DA. Although not shown, the second interlayer insulating layer ILD2 may be disposed between the gate insulating layer GI and the third interlayer insulating layer ILD3 as shown in FIG. 8A, and thus the repair line WDL may be disposed on the second interlayer insulating layer ILD2.

Without being limited thereto, as shown in FIG. 9B, the fourth metal layer SD1 may be electrically connected to the repair line WDL disposed on the gate insulating layer GI through the welding point WP. In this case, the repair line WDL disposed on the first interlayer insulating layer ILD1 may be the first repair line WDL1 electrically connected to the dummy pixel DP of the dummy region DA, and the repair line WDL disposed on the gate insulating layer GI may be the second repair line WDL2.

Since the defective pixel EP and the repair line WDL are electrically connected, signals such as VDD, Vdata, EM, and the like required to normally drive the defective pixel EP and the dummy anode initialization voltage DVar and the like applied to the dummy pixel may be applied to the defective pixel EP through the repair line WDL.

Referring to FIG. 9C, when the double repair lines WDL overlap as shown in FIG. 6B, the repair line WDL disposed on the first interlayer insulating layer ILD1 and the repair line WDL disposed on the gate insulating layer GI may be disposed to overlap in the height direction of the display panel. When the repair lines WDL1 and WDL2 are disposed to overlap, the fourth metal layer SD1 of the defective pixel EP may be electrically connected to the repair line WDL disposed on the first interlayer insulating layer ILD1, and the repair line WDL disposed on the first interlayer insulating layer ILD1 may be cut and disposed as a repair line WDL disposed on the first interlayer insulating layer ILD1 and a repair line WDL disposed on the gate insulating layer GI.

According to the present disclosure, a difference in luminance between a pixel connected to an actual normal pixel circuit and a repaired defective pixel can be improved.

The effects according to the present disclosure are not limited to the above-mentioned effects, and other effects which are not mentioned can be clearly understood by those skilled in the art from the disclosure to be described below.

Although the embodiments of the present disclosure have been described in more detail with reference to the accompanying drawings, the present disclosure is not necessarily limited to these embodiments, and may be variously modified without departing from the technical spirit of the present disclosure. Accordingly, the embodiments disclosed in the present disclosure are not intended to limit the technical spirit of the present disclosure, but to describe the technical spirit of the present disclosure, and the scope of the technical spirit of the present disclosure is not limited by these embodiments. Accordingly, it should be understood that the above-described embodiments are illustrative and not restrictive in all respects. The scope of the present disclosure should be interpreted by the claims, and it should be interpreted that all technical ideas within the equivalent range are included in the scope of the present disclosure.

What is claimed is:

1. A display device, comprising:
a display region in which a plurality of pixels are disposed, each of the plurality of pixels including a light-emitting element;
a dummy region disposed outside the display region, a plurality of dummy pixels disposed in the dummy region; and
a plurality of repair lines crossing the display region and the dummy region along a first direction, at least some of the plurality of repair lines having a double line structure,
wherein at least one defective pixel among the plurality of pixels of the display region is electrically connected to a dummy pixel of the plurality of dummy pixels through a repair line of the plurality of repair lines, and
when a distance between the dummy pixel and the at least one defective pixel connected to each other through the repair line is smaller than a half of a length of the display region in the first direction, the distance between the dummy pixel and the at least one defective pixel connected to each other through the repair line is smaller than a distance from the dummy pixel to a welding position where double lines of the repair line are connected to each other.

2. The display device of claim 1, wherein the display region further includes a plurality of pixel lines disposed in the first direction, and
wherein the plurality of dummy pixels are electrically connected to one of defective pixels disposed along the plurality of pixel lines in a same row.

3. The display device of claim 1, wherein the plurality of repair lines further include a first repair line and a second repair line,
wherein the first repair line is electrically connected to the dummy pixel, and
wherein the second repair line is electrically connected to the at least one defective pixel.

4. The display device of claim 3, wherein the first repair line and the second repair line are disposed in parallel in the first direction.

5. The display device of claim 3, wherein a sum of lengths of each of the plurality of repair lines is constant.

6. The display device of claim 3, wherein a length of the first repair line is longer than a length of the second repair line.

7. The display device of claim 5, wherein the sum of lengths of each of the plurality of repair lines is smaller than the half of the length of the display region in the first direction.

8. The display device of claim 1, wherein, when the distance between the dummy pixel and the at least one defective pixel connected to each other through the repair line is the half of the length of the display region in the first direction, the repair line is disposed as a single line.

9. The display device of claim 1, wherein each of the plurality of pixels further includes a pixel circuit for driving, the pixel circuit comprising:
a light-emitting element;
a driving element electrically connected to the light-emitting element;
a switching element electrically connected to the light-emitting element; and
a capacitor electrically connected to the switching element, and
wherein an anode electrode of the light-emitting element is electrically connected to the repair line.

10. The display device of claim 9, wherein an anode initialization voltage applied to the pixel circuit of a normal pixel among the plurality of pixels and a dummy anode initialization voltage applied to the pixel circuit of the dummy pixel are different from each other.

11. The display device of claim 10, wherein the dummy anode initialization voltage is applied to the dummy pixel through a dummy anode initialization voltage line.

12. The display device of claim 9, wherein a data voltage applied to the pixel circuit of a normal pixel among the plurality of pixels and a dummy data voltage applied to the pixel circuit of the dummy pixel are different from each other.
